(19) United States
(12) Patent Application Publication
(10) Pub. No.: US 2024/0288768 A1
(43) Pub. Date: Aug. 29, 2024

(54) PHOTORESIST COMPOSITION, METHOD FOR FORMING RESIST PATTERN, METHOD FOR MANUFACTURING SEMICONDUCTOR DEVICE, AND SUBSTRATE PROCESSING DEVICE

(71) Applicant: Tokyo Electron Limited, Tokyo (JP)

(72) Inventors: Seiji NAGAHARA, Minato-ku, Tokyo (JP); Congque DINH, Koshi City, Kumamoto (JP); Makoto MURAMATSU, Koshi City, Kumamoto (JP)

(73) Assignee: Tokyo Electron Limited, Tokyo (JP)

(21) Appl. No.: 18/563,382

(22) PCT Filed: May 19, 2022
(86) PCT No.: PCT/JP2022/020852

§ 371 Date: Nov. 22, 2023

(30) Foreign Application Priority Data
Jun. 1, 2021 (JP) 2021-092203

(51) Int. Cl. G03F 7/028; G03F 7/038; G03F 7/16; G03F 7/20; H01L 21/027; H01L 21/308; H01L 21/311; H01L 21/3213

(52) U.S. Cl. CPC G03F 7/028; G03F 7/038; G03F 7/168; G03F 7/2004; G03F 7/2026; H01L 21/0275; H01L 21/3081; H01L 21/3086; H01L 21/31144; H01L 21/32139

(57) ABSTRACT

Disclosed is a photoresist composition comprising a non-chemically amplified resist material and a sensitizer precursor, wherein the sensitizer precursor is a compound that, upon irradiation with ionizing radiation or non-ionizing radiation having a wavelength of 300 nm or less, generates a sensitizer that absorbs non-ionizing radiation having a wavelength more than 300 nm.

### TECHNICAL FIELD

Embodiments of the present disclosure relate to a photoresist composition, a method for forming a resist pattern, a method for manufacturing a semiconductor device, and a substrate processing device.

### BACKGROUND ART

Conventionally, an extreme ultraviolet (EUV) lithography technique using a chemically amplified resist material has been used to form a fine resist pattern having a size of 20 nm. In the case of chemically amplified resist material, generally, the reaction for forming a resist pattern proceeds by the action of an acid catalyst generated by pattern exposure. There is a possibility that the diffusion of the acid catalyst will exert influence and hinder further improvement of resolution.

Incidentally, it has been proposed to use a non-chemically amplified resist material to form a fine resist pattern. For example, there is a report that a cage-shaped compound containing tin oxide functions as a resist material by EUV irradiation (Patent Literature 1 and Non-Patent Literature 1). In addition, a main chain scission-type resist material whose main chain is cut by EUV irradiation has also been proposed (Patent Literatures 2, 3 and 4). Being unlikely to be affected by the diffusion of an acid catalyst, the non-chemically amplified resist material is expected to be more advantageous in forming a resist pattern with higher resolution compared to the chemically amplified resist material.

### CITATION LIST

### Patent Literature

[Patent Literature 1] US Patent Application Publication No. 2020/0064733
[Patent Literature 2] International Publication No. WO2016/132725
[Patent Literature 3] Japanese Unexamined Patent Publication No. 2020-86062
[Patent Literature 4] Japanese Unexamined Patent Publication No. 2020-86455

### Non Patent Literature

[Non-Patent Literature 1] J. Micro/Nanolith. MEMS MOEMS 16(2), 023510 (April-June 2017)

### SUMMARY OF INVENTION

### Technical Problem

In a case where a resist pattern is formed using a photoresist composition containing a non-chemically amplified resist material, further improvement of sensitivity and further reduction of roughness of the resist pattern are desired.

### Solution to Problem

A photoresist composition according to an aspect of the present disclosure contains a non-chemically amplified resist material and a sensitizer precursor. The sensitizer precursor is a compound that, upon irradiation with a first radiation, generates a sensitizer that absorbs a second radiation having a wavelength longer than a wavelength of the first radiation.

By using the photoresist composition described above, it is possible to form a resist film containing a non-chemically amplified resist material and a sensitizer precursor. In a case where a part of the resist film is irradiated with the first radiation, a sensitizer is generated from the sensitizer precursor in the part of the resist film irradiated with the first radiation. In a case where the resist film is irradiated with the second radiation in a batch, the reaction of the non-chemically amplified resist material proceeds, and the reaction is facilitated by the sensitizer. In the state of irradiation with the first radiation, the reaction of the non-chemically amplified resist material does not need to proceed as long as the sensitizer is generated. Therefore, even though the dose of the first radiation is low, the reaction of the non-chemically amplified resist material can sufficiently proceed by the irradiation with the second radiation. That is, the resist pattern can be formed with higher sensitivity. Although the irradiation with the second radiation is necessary, the dose of the first radiation that requires higher energy can be reduced, which is advantageous for the whole process. In addition, according to the knowledge of the inventors of the present invention, the roughness of the resist pattern to be formed is also reduced.

### Advantageous Effects of Invention

In a case where a resist pattern is formed using a photoresist composition containing a non-chemically amplified resist material, the photoresist composition according to the present disclosure can further improve sensitivity and further reduce the roughness of the resist pattern.

### BRIEF DESCRIPTION OF DRAWINGS

FIG. 1 is a flowchart illustrating an example of a method for forming a resist pattern.

FIG. 2 is a process chart illustrating an example of a method for manufacturing a semiconductor device by a method including forming a resist pattern.

FIG. 3 is a process chart illustrating an example of a method for manufacturing a semiconductor device by a method including forming a resist pattern.

FIG. 4 is a process chart illustrating an example of a method for manufacturing a semiconductor device by a method including forming a resist pattern.

FIG. 5 is a flowchart illustrating an example of a method for forming a resist pattern.

FIG. 6 is a flowchart illustrating an example of a method for forming a resist pattern.

FIG. 7 is a schematic view illustrating an example of a substrate processing device.

FIG. 8 is a schematic view illustrating an example of a substrate processing device.

FIG. 9 is a graph illustrating a relationship between the thickness of a resist film and dose of a KrF excimer laser.

FIG. 10 is a graph illustrating a relationship between a critical dimension (CD) and an irradiation dose (relative value) of EUV.

FIG. 11 is a graph illustrating a relationship between a critical dimension (CD) and an irradiation dose (relative value) of EUV.

FIG. 12 is a graph illustrating a relationship between an increase rate of CD and an exposure amount of ultraviolet rays.

### DESCRIPTION OF EMBODIMENTS

Hereinafter, embodiments according to the present disclosure will be described as examples for explaining the present invention. However, the present invention is not limited to what will be described below. In the following description, in some cases, the same components or the components having the same functions will be represented by the same reference numerals to avoid redundant description.

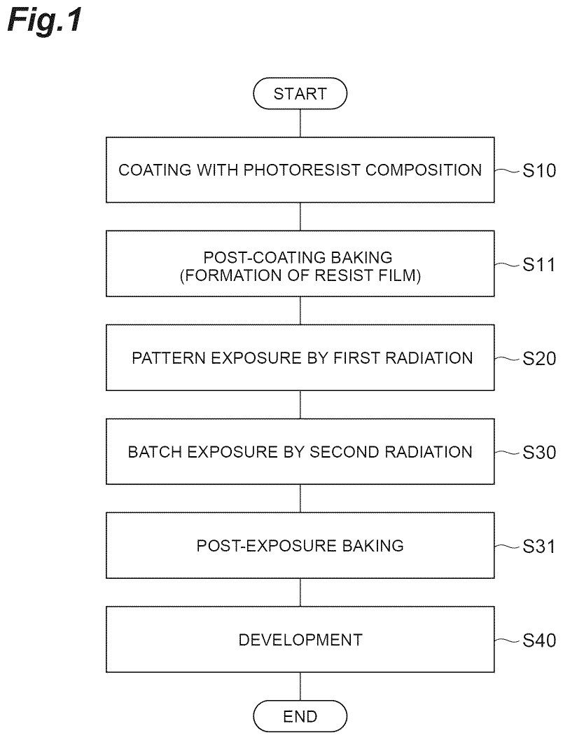

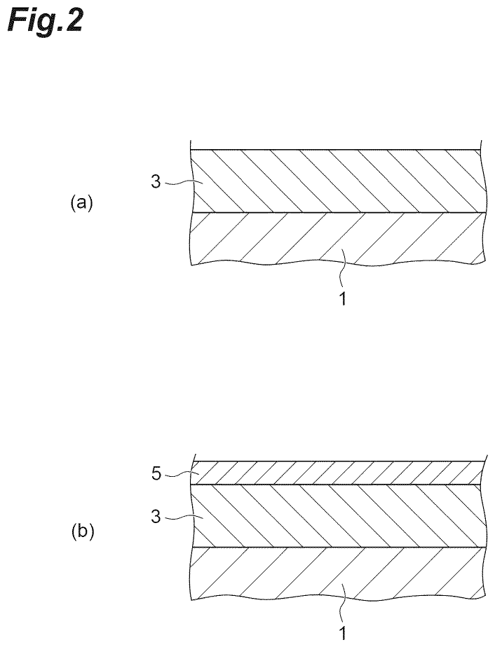

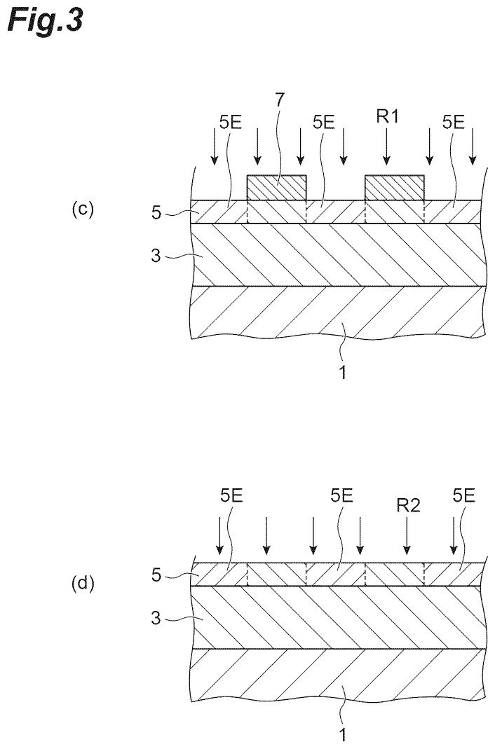

FIG. 1 is a flowchart illustrating an example of a method for forming a resist pattern. FIGS. 2, 3 and 4 are process charts illustrating examples of a method for forming a resist pattern and a method for manufacturing a semiconductor device including forming a resist pattern by the method.

The method for forming a resist pattern illustrated in FIGS. 1 to 4 include, in the following order, a step S10 of coating an etching target film 3 provided on a semiconductor wafer 1 with a photoresist composition, a step S11 of forming a resist film 5 by baking the photoresist composition with which the etching target film 3 is coated, a step S20 as pattern exposure of irradiating a part (5E) of the resist film 5 with a first radiation R1, a step S30 as batch exposure of irradiating the entire region including the part 5E irradiated with the first radiation R1 and other parts in the resist film 5 with a second radiation R2 in a batch, the second radiation R2 having a wavelength longer than a wavelength of the first radiation R1, a step S31 of baking the resist film 5 having undergone the batch exposure, and a step S40 of removing a part of the resist film 5 by contact with a developer solution to form a resist pattern 5A having a trench 5a in which the etching target film 3 is exposed. FIGS. 2 to 4 illustrate examples of steps in a case where the resist film 5 is a negative resist. The first radiation R1 is ionizing radiation or non-ionizing radiation, and the second radiation R2 is non-ionizing radiation. In a case where the first radiation R1 is non-ionizing radiation, the second radiation R2 is non-ionizing radiation having a wavelength longer than the wavelength of the first radiation.

The photoresist composition used to form the resist film 5 contains a non-chemically amplified resist material and a sensitizer precursor. The sensitizer precursor is a compound generating a sensitizer that absorbs the second radiation R2 by irradiation with the first radiation R1.

The non-chemically amplified resist material is a resist material that those skilled in the art understand as a resist material other than the chemically amplified resist material, and experiences a change in solubility in a developer solution without generating an acid catalyst by being irradiated with radiation. Examples of the non-chemically amplified resist material include a metal oxide photoresist material and a main chain scission-type resist material.

The metal oxide photoresist material can contain, for example, an organic metal compound containing a metal oxide having a metal atom and an organic ligand bonded to the metal atom. The metal oxide photoresist material may be nanoparticles (particles having a maximum width less than 1 μm). The metal oxide may be a cage-shaped compound. The metal oxide photoresist material containing an organic metal compound is considered to form a crosslinked structure through reactions including dissociation of the organic ligand from the metal atom by the irradiation with radiation (particularly, the second radiation R2) and bonding of the metal atoms after the dissociation of the organic ligand via an oxygen atom or the like by a condensation reaction. A hydroxyl group is generated by the dissociation of the organic ligand, and a crosslinked structure can be formed by a condensation reaction between the hydroxyl groups. The condensation reaction can be facilitated by baking of the resist film 5 having been subjected to the batch exposure to the second radiation R2. The formed crosslinked structure is substantially insoluble in a developer solution. Therefore, the metal oxide photoresist material can function as a negative resist material. In a case where the metal oxide photoresist material is nanoparticles, the plurality of nanoparticles is linked to each other and can form an aggregate that is substantially insoluble in a developer solution. When absorbing the second radiation R2, the sensitizer generated from the sensitizer precursor mainly facilitates the reaction in which organic ligand dissociation occurs and leads to generation of a hydroxyl group and a condensation reaction in which the metal atoms from which the organic ligand is dissociated are bonded to each other.

At a point in time when hydroxyl groups have been generated by the organic ligand dissociation but the condensation reaction has not yet proceeded much, the metal oxide photoresist material can have high solubility in an alkaline developer solution. On the other hand, the resist film in the part where most of the organic ligands and sensitizer precursors remain without being subjected to irradiation with the first radiation R1 is substantially insoluble in an alkaline developer solution in general. Taking advantage of this point makes it possible to cause the metal oxide photoresist material to function as a positive resist material. In terms of the combination of generation of a sensitizer by irradiation with the first radiation R1 and organic ligand dissociation by irradiation with the second radiation R2 in the presence of a sensitizer, the metal oxide photoresist material as a positive resist material functions based on the same action as that of a metal oxide photoresist material as a negative resist material. Therefore, the metal oxide photoresist material as a positive resist material can also further improve sensitivity and further reduce the roughness of a resist pattern.

The metal oxide of the metal oxide photoresist material may contain, for example, at least one metal atom selected from the group consisting of Sn, Sb, In, Ti, Zr, Hf, V, Co, Mo, W, Al, Ga, Si, Ge, P, As, Y, La, Ce, and Lu. The organic ligand bonded to the metal atom of the metal oxide may be, for example, a branched or non-branched alkyl group that may have a substituent or a cycloalkyl group that may have a substituent. The alkyl group and the cycloalkyl group can be bonded to a metal atom at a primary, secondary, or tertiary carbon atom. The alkyl group and the cycloalkyl group may have 1 to 30 carbon atoms. Examples of the alkyl group as the organic ligand include a methyl group, an ethyl group, an n-propyl group, an isopropyl group, an n-butyl group, a sec-butyl group, a tert-butyl group, and an n-octyl group. Examples of the cycloalkyl group as the organic ligand include a cyclobutyl group, a cyclopropyl group, a cyclohexyl group, a 1-adamantyl group, and a 2-adamantyl group. Examples of substituents that the alkyl group and the cycloalkyl group can have include a cyano group, an alkylthio group, a carbonyl group, an alkyloxy group, an alkylcarbonyl group, an alkylcarbonyloyl group, and a halogeno group. The nanoparticles containing cage-shaped tin oxide and an organic ligand can be, for example, a compound represented by Formula: [(SnR)₁₂O₁₄(OH)₆](OH)₂ (R represents an organic ligand).

The main chain scission-type resist material is a polymer material having a main chain that is cut by irradiation with the second radiation R2 in the presence of a sensitizer generated from the sensitizer precursor. Usually, the main chain scission-type resist material functions as a positive resist. The main chain scission-type resist material may be, for example, a copolymer containing an α-alkylstyrene unit and an α-haloacrylic acid alkyl unit. This copolymer may be a copolymer containing α-methylstyrene unit and α-chloroacrylic acid methyl ester unit.

The sensitizer precursor may be, for example, a compound that generates a sensitizer having a carbonyl group, and examples thereof include an acetal compound, a ketal compound, a thioacetal compound, an alcohol compound, a thiol compound, and an orthoester compound.

The acetal compound, the ketal compound, and the thioacetal compound that can be used as the sensitizer precursor may be, for example, a compound represented by the following Formula (1), and the compound is converted into a ketone compound represented by Formula (1A) by the irradiation with the first radiation R1.

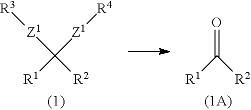

In Formulas (1) and (1A), Z¹ represents an oxygen atom or a sulfur atom. In Formulas (1) and (1A), R¹ represents an aryl group that may have a substituent (for example, a phenyl group, a naphthyl group, or an anthracenyl group), or a conjugated diene group that may have a substituent. In Formulas (1) and (1A), R² represents a hydrogen atom, a halogen atom, an aryl group that may have a substituent (for example, a phenyl group, a naphthyl group, or an anthracenyl group), a conjugated diene group that may have a substituent, a hydrocarbon group having 1 to 30 or 1 to 5 carbon atoms that may have a substituent (for example, an alkyl group), an alkanoyl group having an alkyl group with 1 to 12 carbon atoms that may have a substituent, an amino group, or an aminocarbonyl group. In Formulas (1) and (1A), R³ and R⁴ each independently represent a hydrocarbon group having 1 to 30 or 1 to 5 carbon atoms that may have a substituent (for example, an alkyl group). R¹ and R² may be bonded to each other directly or through a divalent group to form a cyclic structure. R³ and R⁴ may be bonded to each other directly or through a divalent group to form a cyclic structure.

Examples of the divalent group forming a cyclic structure formed by R¹ to R⁴ include —CH₂—, —O—, —S—, —SO₂—, —SO₂NH—, —C(═)O)—, —C(═O)O—, —NHCO—, —NHC(═O)NH—, —CHR^{A}—, —CR^{A}₂−, —NH—, and —NR^{A}−. R^{A} represents a phenyl group, a phenoxy group, or a halogen atom. The phenyl group and the phenoxy group as R^{A} may be substituted with a hydrocarbon group having 1 to 30 or 1 to 5 carbon atoms (for example, an alkyl group), a hydroxyl group, or an alkyl group having 1 to 5 carbon atoms.

Examples of the substituent that the aryl group and the non-conjugated diene group as R¹ or R² can have include a hydrocarbon group having 1 to 30 or 1 to 5 carbon atoms (for example, an alkyl group), a hydroxyalkoxy group having 1 to 5 carbon atoms, a hydroxyalkyl group having 1 to 5 carbon atoms, an alkoxy group having 1 to 5 carbon atoms that may have a substituent, an amino group, an aminocarbonyl group, and a hydroxyl group. Examples of the substituent that the hydrocarbon group, the alkanoyl group, and the alkoxy group as R¹ to R⁴ can have include an alkoxy group having 1 to 5 carbon atoms, an alkoxycarbonyl group having an alkyl group with 1 to 5 carbon atoms, a cycloalkoxycarbonyl group having a cycloalkyl group with 5 to 30 carbon atoms, a furyl group, a phenoxy group, a naphthoxy group, an anthracenoxy group, an amino group, an aminocarbonyl group, and a hydroxyl group.

The acetal compound in which R³ and R⁴ are alkyl groups directly bonded to each other is represented, for example, by the following formulas. In these formulas, substituents such as an alkyl group having 1 to 5 carbon atoms, a cycloalkyl group having 3 to 30 carbon atoms, an alkoxy group having 1 to 5 carbon atoms, alkoxycarbonyl group having an alkyl group with 1 to 5 carbon atoms, a cycloalkoxycarbonyl group having a cycloalkyl group with 5 to 30 carbon atoms, a furyl group, a phenoxy group, a naphthoxy group, an anthracenoxy group, an amino group, an aminocarbonyl group, and a hydroxyl group may be bonded to the carbon atoms configuring the cyclic structure.

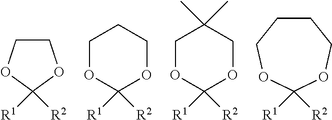

The alcohol compound and the thiol compound that can be used as the sensitizer precursor may be, for example, a compound represented by the following Formula (2), and this compound is converted into a ketone compound represented by Formula (2A) by the irradiation with the first radiation R1.

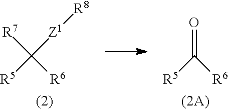

In Formula (2) and Formula (2A), Z¹ represents an oxygen atom or a sulfur atom. In Formulas (2) and (2A), R⁵ represents an aryl group that may have a substituent (for example, a phenyl group, a naphthyl group, or an anthracenyl group), or a conjugated diene group that may have a substituent. In Formulas (2) and (2A), R⁶ represents an aryl group that may have a substituent (for example, a phenyl group, a naphthyl group, or an anthracenyl group), a conjugated diene group that may have a substituent, a hydrocarbon group having 1 to 30 or 1 to 5 carbon atoms that may have a substituent (for example, an alkyl group), an alkanoyl group having an alkyl group with 1 to 12 carbon atoms that may have a substituent, an amino group, or an aminocarbonyl group. In Formulas (2) and (2A), R⁷ represents a hydrogen atom or a halogen atom. In Formulas (2) and (2A), RR represents a hydrogen atom. R⁵ and R⁶ may be bonded to each other directly or through a divalent group to form a cyclic structure. The aryl group and the non-conjugated diene group as R⁵ or R⁶ may have the same substituents as the substituents that the aryl group and the conjugated diene group as R¹ or R² can have. The divalent groups configuring the cyclic structure formed by R⁵ and R⁶ can be the same groups as the divalent groups configuring the cyclic structure formed by R¹ to R⁴.

The orthoester compound that can be used as the sensitizer precursor may be, for example, a compound represented by Formula (3) or (4), and each of these compounds is converted into an ester compound represented by Formula (3A) or a carboxylic acid compound represented by Formula (4A) by the irradiation with the first radiation.

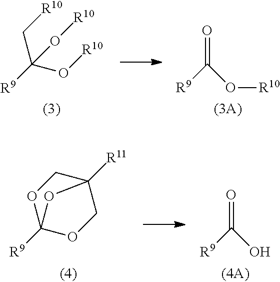

In Formulas (3) and (4), R⁹ represents an aryl group that may have a substituent (for example, a phenyl group, a naphthyl group, or an anthracenyl group group). In Formulas (3) and (4), R¹⁰ represents a hydrocarbon group having 1 to 30 or 1 to 5 carbon atoms that may have a substituent (for example, an alkyl group). A plurality of R¹⁰s in the same molecule may be the same as or different from each other. Examples of the substituent that the aryl group as R⁹ can have include an alkyl group having 1 to 30 or 1 to 5 carbon atoms, an aryloxy group, an arylalkyl group having an alkyl group having 1 to 5 carbon atoms, an arylalkyloxy group having an alkyl group having 1 to 5 carbon atoms, a hydroxyalkoxy group having 1 to 5 carbon atoms, a hydroxyalkyl group having 1 to 5 carbon atoms, an alkoxy group having 1 to 5 carbon atoms, an amino group, an aminocarbonyl group, and a hydroxyl group. The aryl group as R⁹ may include two or more aromatic rings bonded to each other directly or through a divalent group at two or more sites. R¹¹ in Formula (4) represents a hydrogen atom, a hydrocarbon group (for example, an alkyl group) having 1 to 30 or 1 to 5 carbon atoms that may have a substituent, an aryl group that may have a substituent (for example, a phenyl group, a naphthyl group, or an anthracenyl group), an alkoxy group having 1 to 5 carbon atoms that may have a substituent, or an aryloxy group (for example, a phenoxy group, a naphthoxy group, or an anthracenoxy group) that may have a substituent. Examples of the substituent that the hydrocarbon group, the aryl group, the alkoxy group, and the aryloxy group as R¹¹ can have include an alkoxy group having 1 to 5 carbon atoms, an alkoxycarbonyl group having an alkyl group with 1 to 5 carbon atoms, a cycloalkoxycarbonyl group having a cycloalkyl group with 5 to 30 carbon atoms, a furyl group, a phenoxy group, a naphthoxy group, an anthracenoxy group, an amino group, an aminocarbonyl group, and a hydroxyl group.

More specific examples of the ketal compound that can be used as the sensitizer precursor include compounds represented by the following Formula (11) or (12).

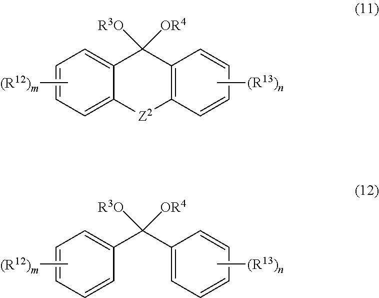

In Formulas (11) and (12), R³ and R⁴ have the same definition as R³ and R⁴ in Formula (1), R¹² and R¹³ each independently represent a hydrocarbon group (for example, an alkyl group) having 1 to 30 or 1 to 5 carbon atoms, a hydroxyalkoxy group having 1 to 5 carbon atoms, a hydroxyalkyl group having 1 to 5 carbon atoms, an alkoxy group having 1 to 5 carbon atoms that may have a substituent, an amino group, an aminocarbonyl group, or a hydroxyl group, and two R's or R¹³s may be bonded to each other directly or through a divalent group to form a cyclic structure. m and n each independently represent an integer of 0 to 4, and a plurality of R¹²s and R¹³s in the same molecule may be the same as or different from each other. In Formula (11), Z² represents a divalent group selected from —O—, —S—, and —NR^{A}—. R^{A} is the same group as R^{A} described above. Examples of the substituent that the alkoxy group as R¹² or R¹³ can have include an alkyl group having 1 to 5 carbon atoms.

R¹² and R¹³ may be a hydroxyalkoxy group having 1 to 5 carbon atoms, and two R¹²s or two R¹³s may be bonded to each other to form a group represented by the following formula.

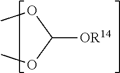

R¹⁴ represents an alkyl group having 1 to 5 carbon atoms. In this case, examples of the acetal compound are represented by the following Formula (11a) or (11b). In Formula (11a), R¹⁵ and R¹⁶ represent an alkyl group having 1 to 5 carbon atoms or a hydroxyalkyl group having 1 to 5 carbon atoms.

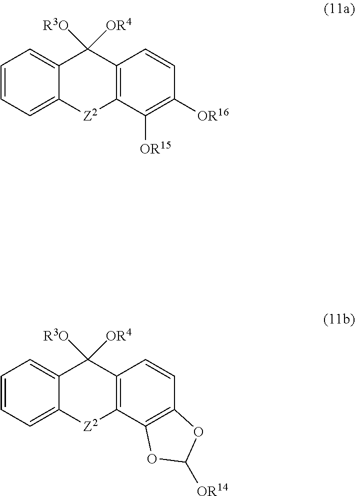

The amount of the sensitizer precursor in the photoresist composition or in the resist film 5 formed of the photoresist composition that has not yet been exposed is adjusted such that the reaction of the non-chemically amplified resist material can be sufficiently facilitated by the irradiation with the second radiation. For example, the amount of the sensitizer precursor may be 0.1 to 40 parts by mass or 1 to 20 parts by mass with respect to 100 parts by mass of the non-chemically amplified resist material.

The photoresist composition may contain a solvent. The solvent is selected from solvents capable of dispersing or dissolving the non-chemically amplified resist material and the sensitizer precursor. Examples of the solvent include ketones such as cyclohexanone and methyl-2-amylketone; alcohols such as 3-methoxybutanol, 3-methyl-3-methoxybutanol, 1-methoxy-2-propanol, and 1-ethoxy-2-propanol; ethers such as propylene glycol monomethyl ether, ethylene glycol monomethyl ether, propylene glycol monoethyl ether, ethylene glycol monoethyl ether, propylene glycol dimethyl ether, and diethylene glycol dimethyl ether; and esters such as propylene glycol monomethyl ether acetate, propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, propylene glycol monomethyl ether acetate, and propylene glycol monotert-butyl ether acetate.

The amount of the solvent in the photoresist composition is adjusted within a range in which the resist film 5 can be appropriately formed by a method such as spin coating. For example, the amount of the solvent may be 500 to 100,000 parts by mass with respect to 100 parts by mass of the non-chemically amplified resist material.

The etching target film 3 is coated with the photoresist composition, for example, by spin coating (step S11). The photoresist composition with which the underlayer film 3 is coated is baked such that the solvent in the photoresist composition is removed (step S20). The resist film 5 formed in advance may be laminated on the etching target film 3. The thickness of the resist film 5 may be, for example, 1 to 5,000 nm, 10 to 1,000 nm, or 30 to 200 nm.

The resist film 5 may be formed using a photoresist composition that contains a non-chemically amplified resist material and a sensitizer precursor and substantially does not contain a solvent. In this case, the resist film 5 is formed, for example, by depositing the photoresist composition on a workpiece having the etching target film 3 by a vapor deposition method such as atomic layer deposition (ALD) or chemical vapor deposition (CVD).

The formed resist film 5 is irradiated with the first radiation R1 through a mask 7 with openings placed on the resist film 5 (step S20). As a result, in the resist film 5, the part (5E) exposed in the openings of the mask 7 is irradiated with the first radiation R1 having a pattern corresponding to the openings. In the part 5E irradiated with the first radiation R1, a sensitizer is generated from the sensitizer precursor.

The first radiation R1 may be ionizing radiation or non-ionizing radiation having a wavelength of 300 nm or less. The light source of the first radiation R1 may be, for example, an electron beam of 1 key to 200 key, extreme ultraviolet rays (EUV) having a wavelength of 13.5 nm, a 193 nm excimer laser (ArF excimer laser), or a 248 nm excimer laser (KrF excimer laser). The dose of the first radiation may be, for example, 100 to 200 mJ/cm². The exposure with the first radiation R1 can be performed by immersion lithography or dry lithography. The first radiation R1 may be radiated along a predetermined pattern instead of using a mask.

After the resist film is irradiated with the first radiation R1, the mask 7 is removed, and then the entire region including the part 5E irradiated with the first radiation R1 and other parts in the resist film 5 is irradiated with the second radiation R2 in a batch (step S30, batch exposure). When the resist film is irradiated with the second radiation R2, in the part 5E irradiated with the first radiation R1, the reaction of the non-chemically amplified resist material proceeds in the presence of a sensitizer, which selectively changes the solubility of the part 5E in a developer solution. The time from the end of the irradiation with the first radiation R1 to the start of the irradiation with the second radiation R2 may be 4 to 120 seconds.

The second radiation R2 is non-ionizing radiation. In a case where the first radiation R1 is ionizing radiation, the second radiation R2 is non-ionizing radiation having a wavelength longer than the wavelength of the first radiation R1. For example, the second radiation R2 may be non-ionizing radiation (for example, ultraviolet rays) having a wavelength more than 300 nm. The light source of the second radiation R2 may be, for example, a mercury lamp, a xenon lamp, or LED. The dose of the second radiation may be, for example, 0.01 to 10 J/cm². The exposure by the second radiation R2 can be performed by immersion lithography or dry lithography.

After the batch exposure with the second radiation R2, the resist film 5 is baked (step S31). By the post-exposure baking the roughness of the resist pattern 5A to be formed can be further reduced. The heating for post-exposure baking can be performed in the atmosphere or in an inert gas atmosphere such as nitrogen or argon. The heating temperature may be 50° C. to 200° C., and the heating time may be 10 to 300 seconds.

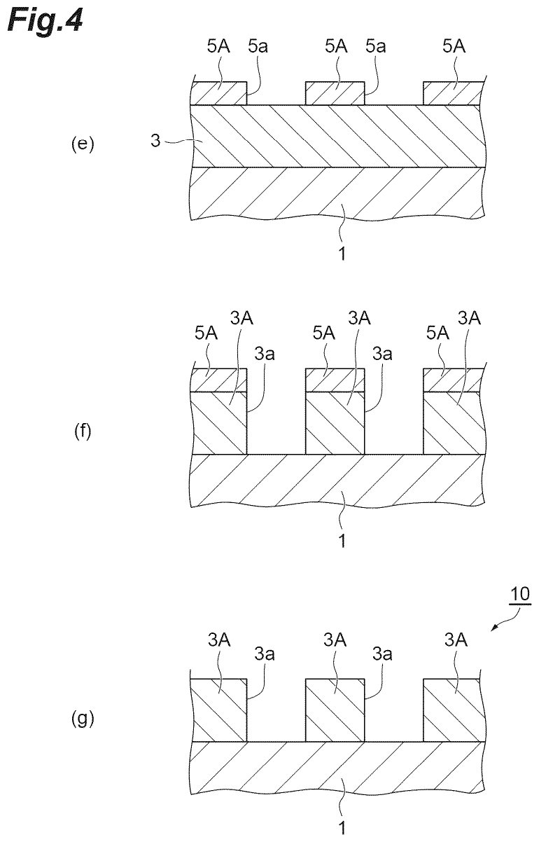

Subsequently, a part of the resist film 5 is removed by development such that the resist pattern 5A having the trench 5a in which the etching target film 3 is exposed is formed (step S40, (a) of FIG. 4). In a case where the resist film 5 is a negative resist, the part 5E irradiated with the first radiation R1 substantially does not dissolve in a developer solution, and remains as the resist pattern 5A. In a case where the resist film 5 is a positive resist, contrary to the embodiment illustrated in the drawing, the part 5E irradiated with the first radiation R1 is removed, and other parts remain as the resist pattern 5A.

The development of the resist film 5 may include removing a part of the resist film 5 by contact with a developer solution. The developer solution is selected from substances that efficiently dissolve the part 5E irradiated with the first radiation R1 or other parts. For example, the developer solution can be an organic developer solution or an alkaline developer solution.

In a case where the non-chemically amplified resist material is a metal oxide photoresist material, the developer solution may be an organic developer solution or an alkaline developer solution. In a case where a resist film containing a metal oxide photoresist material is used as a negative resist, usually, an organic developer solution is used. In a case where a resist film containing a metal oxide photoresist material is used as a positive resist, usually, an alkaline developer solution is used.

The organic developer solution used for the development of a resist film containing a metal oxide photoresist material includes, for example, ketones, alcohols, esters, organic acids, or a combination of these. Examples of ketones include 2-octanone, 2-nonanone, 2-heptanone, 3-heptanone, 4-heptanone, 2-hexanone, 3-hexanone, diisobutylketone, methylcyclohexanone, acetophenone, and methylacetophenone. Examples of the alcohols include methylisobutylcarbinol (MIBC), methyl alcohol, ethyl alcohol, isopropyl alcohol, and butanol. Examples of the esters include propylene glycol monomethyl ether acetate (PGMEA), heptyl acetate, 1-methylheptyl acetate, octyl acetate, 1-methyloctyl acetate, nonyl acetate, decyl acetate, undecyl acetate, dodecyl acetate, tetradecyl acetate, pentadecyl acetate, hexadecyl acetate, heptadecyl acetate, octadecyl acetate, nonadecyl acetate, eicosyl acetate, propyl acetate, butyl acetate, isobutyl acetate, amyl acetate, butenyl acetate, isoamyl acetate, and ethyl butyrate. Examples of the organic acids include acetic acid and butyric acid.

The alkaline developer solution used to develop the resist film containing a metal oxide photoresist material may be a solution (for example, an aqueous solution) containing one or more alkaline compound selected from tetraalkylammonium hydroxide, choline, an alkali metal hydroxide, an alkali metal metasilicate or a hydrate thereof, an alkali metal phosphate or a hydrate thereof, ammonia, alkylamine, alkanolamine, and a heterocyclic amine. The alkaline developer solution may be an aqueous tetramethylammonium hydroxide solution. As necessary, the alkaline developer solution may contain additional components selected from water-soluble organic solvents such as methanol and ethanol, surfactants, and the like. After development with an alkaline developer solution, rinsing with rinsing liquids such as water and an organic solution may be performed.

In a case where the non-chemically amplified resist material is a main chain scission-type resist material, the developer solution may be an organic developer solution. The organic developer solution contains, for example, ketones, alcohols, esters, or a combination of these. Examples of ketones include 2-octanone, 2-nonanone, 2-heptanone, 3-heptanone, 4-heptanone, 2-hexanone, 3-hexanone, diisobutylketone, methylcyclohexanone, acetophenone, and methylacetophenone. Examples of the alcohols include methylisobutylcarbinol (MIBC), methyl alcohol, ethyl alcohol, isopropyl alcohol, and butanol. Examples of the esters include propylene glycol monomethyl ether acetate (PGMEA), heptyl acetate, 1-methylheptyl acetate, octyl acetate, 1-methyloctyl acetate, nonyl acetate, decyl acetate, undecyl acetate, dodecyl acetate, tetradecyl acetate, pentadecyl acetate, hexadecyl acetate, heptadecyl acetate, octadecyl acetate, nonadecyl acetate, eicosyl acetate, propyl acetate, butyl acetate, isobutyl acetate, amyl acetate, butenyl acetate, and isoamyl acetate.

The development of the resist film 5 may include removing a part of the resist film 5 by dry development. The dry development may be, for example, plasma etching or chemical etching.

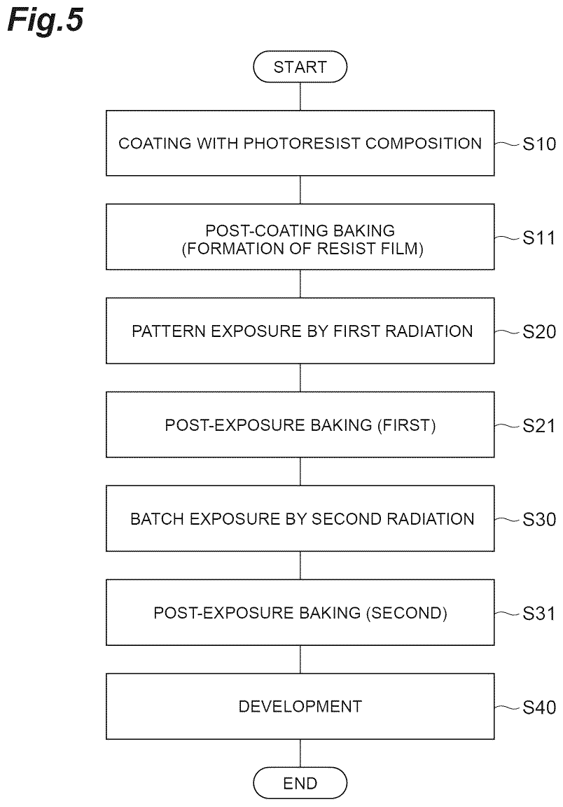

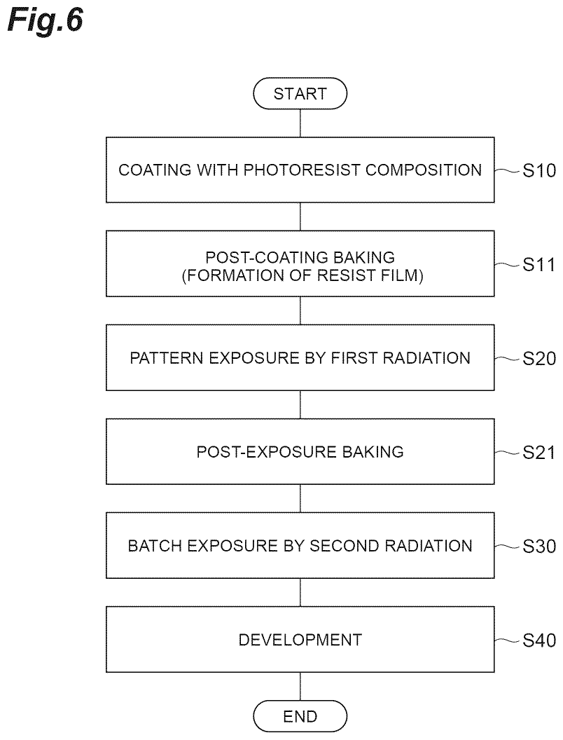

FIGS. 5 and 6 are flowcharts illustrating another example of a method for forming a resist pattern.

The method illustrated in FIG. 5 further includes a step S21 of baking the resist film after the pattern exposure by the first radiation (step S20), prior to the batch exposure (step S30) by the second radiation. The addition of the first baking (step S21) after the pattern exposure makes it possible to further reduce the roughness of the resist pattern 5A to be formed. The heating conditions for the first baking (step S21) after the pattern exposure may be the same as the heating conditions exemplified above for the baking (step S31) after the batch exposure. As in the method illustrated in FIG. 6, baking after pattern exposure (step S21) may be introduced, and the baking after batch exposure may not be performed.

As illustrated in (f) and (g) of FIG. 4, the method for manufacturing a semiconductor device further includes etching the etching target film 3 exposed in the trench 5a of the resist pattern 5A such that an etching target film 3A is patterned to form a trench 3a is formed. The method of etching the etching target film 3 can be selected in consideration of the type of material configuring the etching target film 3 and the like. For example, dry etching or wet etching may be used. After the etching, the resist pattern 5A may be removed. By the method illustrated in FIG. 4, a processed substrate 10 having the semiconductor wafer 1 and the patterned etching target film 3A is obtained.

The patterned etching target film 3A may be an active layer, a lower layer insulating film, a gate electrode film, or an upper layer insulating film. Wiring may be embedded in the trench 3a of the etching target film 3A. By the method according to the present disclosure, for example, it is possible to manufacture a semiconductor device including a semiconductor substrate and an integrated circuit including a patterned etching target film formed on the semiconductor substrate.

By the etching using the resist pattern formed by the method according to the present disclosure as a mask, it is also possible to manufacture a mask for lithography or template for nanoimprinting. The mask for lithography may be a transmissive mask or a reflective mask.

For the method exemplified above, for example, it is possible to use a substrate processing device mainly configured with a film forming unit that forms a resist film containing a non-chemically amplified resist material and a sensitizer precursor on a workpiece having an etching target film, an exposure unit that radiates a second radiation to the resist film having a part irradiated with a first radiation, a development unit that removes a part of the resist film by contact with a developer solution to form a resist pattern, and a control unit that controls the exposure unit such that the entire region including the part irradiated with the first radiation and other parts in the resist film is irradiated with the second radiation in a batch. The film forming unit may include a coating unit that coats the workpiece having en etching target film with a photoresist composition and a heat treatment unit that bakes the photoresist composition, with which the workpiece is coated, to form a resist film on the etching target film.

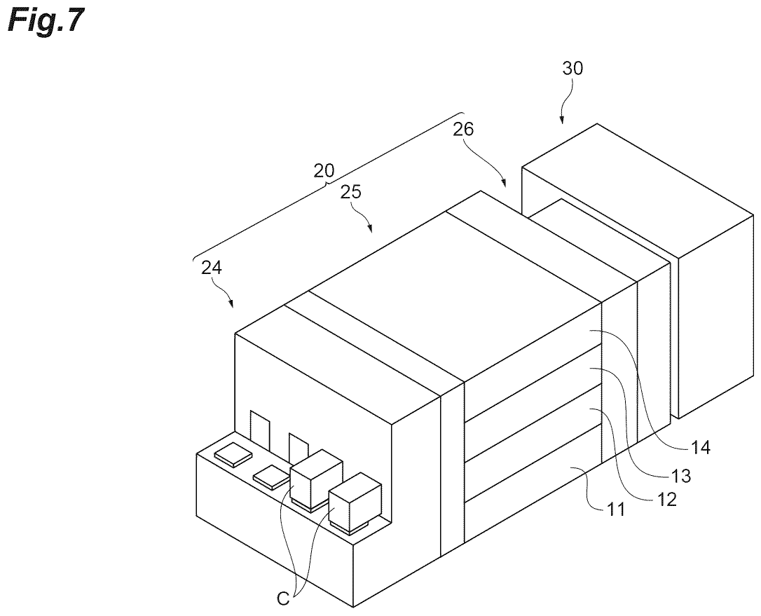

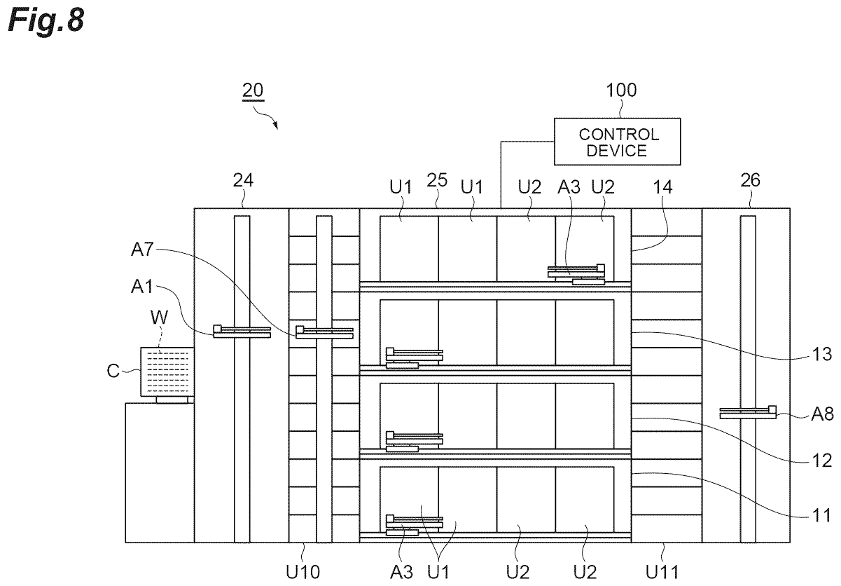

FIGS. 7 and 8 are schematic views illustrating an example of a substrate processing device. FIG. 7 also illustrates an example of an exposure device used in combination with the substrate processing device. FIG. 8 illustrates an example of an internal configuration of a substrate processing device 20 illustrated in FIG. 7. The substrate processing device 20 illustrated in FIGS. 7 and 8 includes a carrier block 24, a processing block 25, and an interface block 26. The workpiece W is processed with the substrate processing device 20 by the above method.

The carrier block 24 is a block configured to introduce the workpiece W into the substrate processing device 20 and to take the workpiece W out of the substrate processing device 20. The carrier block 24 has a transport device A1 including a delivery arm. The transport device A1 takes out the workpiece W stored in a carrier C, passes the workpiece W to the processing block 25, receives the workpiece W from the processing block 25, and returns the workpiece W back into the carrier C.

The processing block 25 has processing modules 11, 12, 13, and 14, which are laminated in this order. The processing modules 11, 12, 13, and 14 each have a plurality of built-in processing units U1 and U2, and a built-in transport device A3 that transports the workpiece W to these processing units.

The processing module 11 may be configured to form an underlayer film (etching target film) on the surface of a substrate (for example, a semiconductor wafer) as the workpiece W. In the processing module 11, for example, the processing unit U1 may be a liquid processing unit that coats the workpiece W with a coating liquid for forming an underlayer film, and the processing unit U2 may be a heat treatment unit that thermally treats the coating liquid with which the workpiece W is coated to form an underlayer film.

The processing module 12 may be configured to form a resist film on the underlayer film (etching target film) of the workpiece W. In the processing module 12, for example, the processing unit U1 may be a coating unit that coats the workpiece W with a photoresist composition, and the processing unit U2 may be a heat treatment unit that bakes the photoresist composition with which the workpiece W is coated to form a resist film. In this case, the film forming unit that forms a film of the photoresist composition is configured with the coating unit and the heat treatment unit. The workpiece W having the resist film may be transported to an exposure device 30 through the interface block 26, and a part of the resist film may be irradiated with the first radiation in the exposure device 30. Instead of or in addition to the coating unit, a film forming unit that deposits a photoresist composition on the workpiece W to form a resist film may be provided.

The processing module 13 may be configured to irradiate the resist film having a part irradiated with the first radiation in the exposure device 30 with the second radiation. In the processing module 13, for example, the processing unit U1 may be an exposure unit having a light source of the second radiation, and the processing unit U2 may be a heat treatment unit for baking the resist film that is not yet irradiated with the second radiation or has been irradiated with the second radiation.

The processing module 14 may be configured to function as a development unit which removes a part of the resist film irradiated with the second radiation by contact with a developer solution such that a resist pattern is formed. In the processing module 14, for example, the processing unit U1 may be a liquid processing unit that supplies a developer solution and, as necessary, a rinsing liquid to the resist film, and the processing unit U2 may be a heat treatment unit for thermally treating the resist film before or after development. The processing module 14 may be configured to function as a development unit which removes a part of the resist film irradiated with the second radiation by dry development such that a resist pattern is formed.

The processing block 25 further has a shelf unit U10 provided on the carrier block 24 side. The shelf unit U10 is divided into a plurality of cells arranged in the vertical direction. A transport device A7 including a lifting arm is provided near the shelf unit U10. The transport device A7 moves the workpiece W up and down between cells of the shelf unit U10. The processing block 25 has a shelf unit U11 provided on the interface block 26 side. The shelf unit U11 is divided into a plurality of cells arranged in the vertical direction.

The interface block 26 is configured to deliver the workpiece W between the processing block 25 and the exposure device 30. The interface block 26 has a built-in transport device A8 (transport unit) including a delivery arm. The transport device A8 delivers the workpiece W disposed in the shelf unit U11 to the exposure device 30. The transport device A8 receives the workpiece W from the exposure device 30 and returns the workpiece W back to the shelf unit U1.

The control device 100 (control unit) controls the units configuring each block such that a target resist pattern is formed in the workpiece W. For example, the control device 100 controls the exposure unit (for example, the processing unit U1 in the processing module) such that the entire region including the part irradiated with the first radiation and other parts in the resist film is irradiated with the second radiation in a batch. In addition, the control device 100 can also control the transport unit (transport device A8) of the interface block 26 such that the workpiece having the resist film irradiated with the first radiation is transported to the exposure unit in the exposure device 30.

The specific configuration of the substrate processing device is not limited to the configuration of the substrate processing device 20 illustrated above. For example, an exposure unit that radiates the second radiation to the resist film having the part irradiated with the first radiation may be provided between the processing block and the interface block.

Exemplary embodiments included in the present disclosure are described below.

[E1]

A photoresist composition comprising:
a non-chemically amplified resist material; and
a sensitizer precursor;
wherein the sensitizer precursor is a compound that, upon irradiation with ionizing radiation or non-ionizing radiation having a wavelength of 300 nm or less, generates a sensitizer that absorbs non-ionizing radiation having a wavelength more than 300 nm.

[E2]

The photoresist composition according to [E1],
wherein the non-chemically amplified resist material is a metal oxide photoresist material.

[E3]

The photoresist composition according to [E1],
wherein the non-chemically amplified resist material is a main chain scission-type resist material.

[E4]

The photoresist composition according to any one of [E1] to [E3],
wherein the sensitizer precursor comprises at least one compound that generates the sensitizer having a carbonyl group and is selected from the group consisting of an acetal compound, a ketal compound, a thioacetal compound, an alcohol compound, a thiol compound, and an orthoester compound.

[E5]

The photoresist composition according to any one of [E1] to [E4], further comprising:
a solvent.

[E6]

A method for forming a resist pattern, comprising, in the following order:
irradiating a part of a resist film comprising a non-chemically amplified resist material and a sensitizer precursor with a first radiation;
irradiating an entire region including the part irradiated with the first radiation and other parts in the resist film with a second radiation in a batch; and
forming a resist pattern by removing a part of the resist film by development,
wherein the first radiation is ionizing radiation or non-ionizing radiation,
the second radiation is non-ionizing radiation,
in a case where the first radiation is non-ionizing radiation, the second radiation is non-ionizing radiation having a wavelength longer than a wavelength of the first radiation, and
the sensitizer precursor is a compound generating a sensitizer that absorbs the second radiation upon irradiation with the first radiation.

[E7]

The method according to [E6],
wherein the non-chemically amplified resist material is a metal oxide photoresist material.

[E8]

The method according to [E6],
wherein the non-chemically amplified resist material is a main chain scission-type resist material.

[E9]

The method according to any one of [E6] to [E8],
wherein the sensitizer precursor comprises at least one compound that generates the sensitizer having a carbonyl group and is selected from the group consisting of an acetal compound, a ketal compound, a thioacetal compound, an alcohol compound, a thiol compound, and an orthoester compound.

[E10]

The method according to any one of [E6] to [E9],
wherein the first radiation is ionizing radiation or non-ionizing radiation having a wavelength of 300 nm or less, and
the second radiation is a non-ionizing radiation having a wavelength more than 300 nm.

[E11]

The method according to any one of [E6] to [E10], further comprising:
baking the resist film between the irradiation with the first radiation and the irradiation with the second radiation, after the irradiation with the second radiation, or between the irradiation with the first radiation and the irradiation with the second radiation and after the irradiation with the second radiation.

[E12]

A method for manufacturing a semiconductor device having a patterned film, the method comprising:
forming a resist pattern on an etching target film by the method according to any one of [E6] to [E11], the resist pattern having a trench in which the etching target film is exposed; and
etching the etching target film exposed in the trench such that the etching target film is patterned.

[E13]

A substrate processing device comprising:
a film forming unit that forms a resist film comprising a non-chemically amplified resist material and a sensitizer precursor on a workpiece having an etching target film;
an exposure unit that irradiates the resist film having a part irradiated with a first radiation with a second radiation;
a development unit that forms a resist pattern by removing a part of the resist film by development; and
a control unit that controls the exposure unit such that an entire region including the part irradiated with the first radiation and other parts in the resist film is irradiated with the second radiation in a batch,
wherein the first radiation is ionizing radiation or non-ionizing radiation,
the second radiation is non-ionizing radiation, and
in a case where the first radiation is non-ionizing radiation, the second radiation is non-ionizing radiation having a wavelength longer than a wavelength of the first radiation.

[E14]

The substrate processing device according to [E13], further comprising:
a processing block that includes the film forming unit, the exposure unit, and the development unit; and
an interface block that includes a transport unit passing a workpiece having the resist film between the processing block and an exposure device irradiating a part of the resist film with the first radiation,
wherein the control unit controls the transport unit such that the workpiece having the resist film irradiated with the first radiation in the exposure device is transported to the exposure unit.

[E15]

The substrate processing device according to [E13] or [E14],
wherein the film forming unit includes a coating unit that coats the workpiece with a photoresist composition comprising the non-chemically amplified resist material and the sensitizer precursor.

[E16]

The substrate processing device according to [E15],
wherein the film forming unit further includes a heat treatment unit that bakes a film of the photoresist composition to form the resist film containing the non-chemically amplified resist material and the sensitizer precursor on the etching target film.

### Examples

Hereinafter, the present disclosure will be more specifically described with reference to examples. However, the present invention is not limited to these examples.

### Preparation of Photoresist Composition

### Photoresist Composition 1

As a non-chemically amplified resist material, nanoparticles having a cage-shaped tin oxide compound and an organic ligand {(SnR)₁₂O₁₄(OH)₆](OH)₂, and R is an alkyl group, sometimes called “MOR” hereinafter) were prepared. An MOR solution having a concentration of 0.01 M was prepared as a photoresist composition 1.

### Photoresist Composition 2

A Ketal compound represented by the following formula was prepared as a sensitizer precursor (PP).

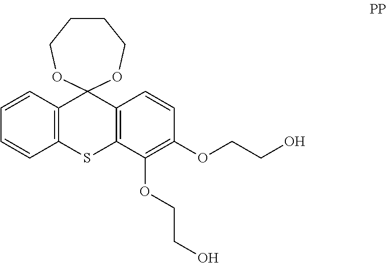 [SMILES: OCCOc1ccc2c(c1OCCO)Sc1ccccc1C21OCCCCO1]

The photoresist composition 1 (33.3 g) and 60 mg of the sensitizer precursor (PP) were mixed to obtain a liquid photoresist composition 2.

### Evaluation 1

### Test 1-1: Photoresist Composition 1 (MOR), No UV Exposure

By using a spin coater, a silicon wafer was coated with the photoresist composition 1. The coating film was heated at 100° C. for 60 seconds to remove the solvent, thereby forming a resist film having a thickness of 22 nm. The entire surface of the baked resist film was exposed to a KrF excimer laser. After the exposure, the resist film was baked by heating at 180° C. for 60 seconds. The baked resist film was subjected to a development process using 2-heptanone. After the development process, the thickness of the resist film was measured using a thickness gauge (Aresis 8350, Toho Technology Corporation). The same test was performed multiple times while changing the dose of the KrF excimer laser. In this way, the relationship between the thickness of the resist film after the development process and the dose of the KrF excimer laser was determined.

### Test 1-2: Photoresist Composition 2 (MOR/PP), No UV Exposure

By using a spin coater, a silicon wafer was coated with the photoresist composition 2. The coating film was heated at 100° C. for 60 seconds to remove the solvent, thereby forming a resist film having a thickness of 22 nm. The entire surface of the baked resist film was exposed to a KrF excimer laser. After the exposure, the resist film was baked by heating at 160° C. for 60 seconds. The baked resist film was subjected to a development process using 2-heptanone. After the development process, the thickness of the resist film was measured using a thickness gauge (Aresis 8350, Toho Technology Corporation). The same test was performed multiple times while changing the dose of the KrF excimer laser. In this way, the relationship between the thickness of the resist film after the development process and the dose of the KrF excimer laser was determined.

Test 1-3: Photoresist Composition 2 (MOR/PP), with UV Exposure

By using a spin coater, a silicon wafer was coated with the photoresist composition 2. The coating film was heated at 100° C. for 60 seconds to remove the solvent, thereby forming a resist film having a thickness of 22 nm. The entire surface of the resist film was exposed to a KrF excimer laser and then to ultraviolet rays having wavelengths of 395 nm and 365 nm. After the exposure, the resist film was baked by heating at 160° C. for 60 seconds. The baked resist film was subjected to a development process using 2-heptanone. After the development process, the thickness of the resist film was measured using a thickness gauge (Aresis 8350, Toho Technology Corporation). The same test was performed multiple times while changing the dose of the KrF excimer laser. In this way, the relationship between the thickness of the resist film after the development process and the dose of the KrF excimer laser was determined.

### Results

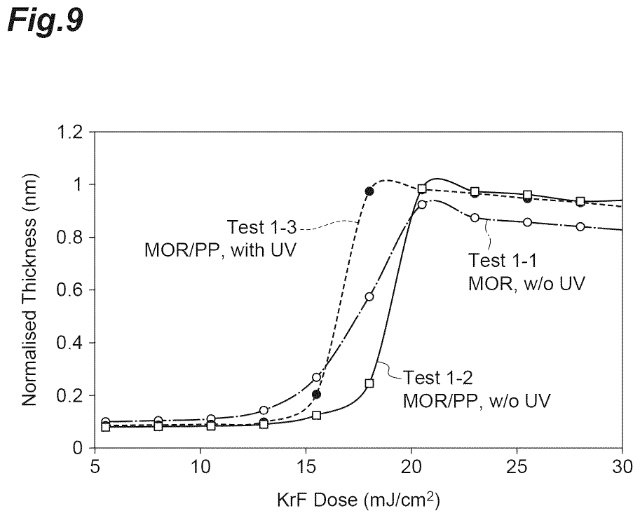

FIG. 9 is a graph illustrating a relationship between the thickness of a resist film after a development process and dose of a KrF excimer laser. In all the tests, the irradiation with radiation at a certain dose made the resist film insoluble in a developer solution (2-heptanone). It has been confirmed that in a case where a photoresist composition containing MOR and a sensitizer precursor (PP) is used as in Test 1-3 and exposure with a KrF excimer laser and the subsequent UV exposure are combined, the resist film can be patterned with lower dose and higher contrast, compared to a case where MOR is used alone as in Test 1-1.

### Evaluation 2

### Test 2-1: Photoresist Composition 1 (MOR), No UV Exposure

An SOC film formed on a silicon wafer was coated with the photoresist composition 1 by using a spin coater. The coating film was heated at 100° C. for 60 seconds to remove the solvent, thereby forming a resist film having a thickness of 22 nm. Through a mask having a pattern corresponding to line/space with a half pitch of 150 nm, the resist film was exposed to a KrF excimer laser. The dose of the radiated KrF excimer laser was 94.3 J/cm². After the exposure, the resist film was baked by heating at 180° C. for 60 seconds. The baked resist film was subjected to a development process using 2-heptanone. After the development process, the formed linear resist pattern was observed with a scanning electron microscope to measure the line edge roughness (LER) of the resist pattern. LER was 28.6 nm.

### Test 2-2: Photoresist Composition 2 (MOR/PP), No UV Exposure

An SOC film formed on a silicon wafer was coated with the photoresist composition 2 by using a spin coater. The coating film was heated at 100° C. for 60 seconds to remove the solvent, thereby forming a resist film having a thickness of 22 nm. Through a mask having a pattern corresponding to line/space with a half pitch of 150 nm, the resist film was exposed to a KrF excimer laser. The dose of the radiated KrF excimer laser was 95.6 J/cm². After the exposure, the resist film was baked by heating at 160° C. for 60 seconds. The baked resist film was subjected to a development process using 2-heptanone. After the development process, the formed linear resist pattern was observed with a scanning electron microscope to measure the line edge roughness (LER) of the resist pattern. LER was 16.3 nm.

Test 2-3: Photoresist Composition 2 (MOR/PP), with UV Exposure

An SOC film formed on a silicon wafer was coated with the photoresist composition 2 by using a spin coater. The coating film was heated at 100° C. for 60 seconds to remove the solvent, thereby forming a resist film having a thickness of 22 nm. Through a mask having a pattern corresponding to line/space with a half pitch of 150 nm, the resist film was exposed to a KrF excimer laser. Immediately thereafter, the mask was removed, and the entire surface of the resist film was exposed to ultraviolet rays having wavelengths of 395 nm and 365 nm. The dose of the KrF excimer laser was 87.6 J/cm², and the dose of the ultraviolet rays was 2.5 J/cm². After the exposure, the resist film was baked by heating at 160° C. for 60 seconds. The baked resist film was subjected to a development process using 2-heptanone. After the development process, the formed linear resist pattern was observed with a scanning electron microscope to measure the line edge roughness (LER) of the resist pattern. LER was 16.2 nm.

Test 2-4: Photoresist Composition 2 (MOR/PP), with UV Exposure

A resist pattern was formed in the same manner as in Example 2-3, except that the dose of the KrF excimer laser was changed to 84.8 J/cm² and the dose of the ultraviolet rays was changed to 5 J/cm², and LER of the resist pattern was measured. LER was 16.0 nm.

### Results

The evaluation results are shown in Table 1. As in Test 2-2, using the photoresist composition containing MOR and a sensitizer precursor (PP) reduces LER of the resist pattern. Furthermore, it has been confirmed that the addition of the step of batch exposure with ultraviolet rays as in Tests 2-3 and 2-4 makes it possible to further reduce the dose of the KrF excimer laser while maintaining the reduced roughness of the resist pattern.

TABLE 1

| | Test 2-1 | Test 2-2 | Test 2-3 | Test 2-3 |
|---|---|---|---|---|
| | MOR | MOR/PP | MOR/PP | MOR/PP |
| KrF Excimer Laser (J/m²) | 94.3 | 95.6 | 87.6 | 84.8 |
| UV (J/cm²) | 0 | 0 | 2.5 | 5 |
| LER (nm) | 28.6 | 16.3 | 16.2 | 16.0 |

### Evaluation 3

### Test 3-1: Photoresist Composition 1 (MOR), No UV Exposure

By using a spin coater, a silicon wafer was coated with the photoresist composition 1. The coating film was heated at 100° C. for 60 seconds to remove the solvent, thereby forming a resist film having a thickness of 22 nm. In a vacuum, the entire surface of the resist film was irradiated with an electron beam at an irradiation current of 100 pA and an acceleration voltage of 150 kV in a line/space pattern with a half pitch of 12 nm. Thereafter, the resist film was baked by heating at 180° C. for 60 seconds. The baked resist film was subjected to a development process using 2-heptanone. After the development process, the formed linear resist pattern was observed with a scanning electron microscope to measure the line width roughness (LWR) and the line edge roughness (LER) of the resist pattern. LWR was 1.7 nm, and LER was 2.1 nm.

### Test 3-2: Photoresist Composition 2 (MOR/PP), No UV Exposure

By using a spin coater, a silicon wafer was coated with the photoresist composition 2. The coating film was heated at 100° C. for 60 seconds to remove the solvent, thereby forming a resist film having a thickness of 22 nm. In a vacuum, the entire surface of the resist film was irradiated with an electron beam at an irradiation current of 100 pA and an acceleration voltage of 150 kV in a line/space pattern with a half pitch of 12 inn. Thereafter, the resist film was baked by heating at 160° C. for 60 seconds. The baked resist film was subjected to a development process using 2-heptanone. After the development process, the formed linear resist pattern was observed with a scanning electron microscope to measure the line width roughness (LWR) and the line edge roughness (LER) of the resist pattern. LWR was 0.99 nm, and LER was 1.8 nm.

Test 3-3: Photoresist Composition 2 (MOR/PP), with UV Exposure

By using a spin coater, a silicon wafer was coated with the photoresist composition 2. The coating film was heated at 100° C. for 60 seconds to remove the solvent, thereby forming a resist film having a thickness of 22 nm. In a vacuum, the entire surface of the resist film was irradiated with an electron beam at an irradiation current of 100 pA and an acceleration voltage of 150 kV in a line/space pattern with a half pitch of 12 nm. Immediately thereafter, the entire surface of the resist film was exposed to ultraviolet rays having a wavelength of 395 nm (exposure amount: 5 J/cm²). The exposed resist film was baked by heating at 160° C. for 60 seconds. The baked resist film was subjected to a development process using 2-heptanone. After the development process, the formed linear resist pattern was observed with a scanning electron microscope to measure the line width roughness (LWR) and the line edge roughness (LER) of the resist pattern. LWR was 0.92 nm, and LER was 1.6 nm.

### Results

The evaluation results are shown in Table 2. It has been confirmed that a resist pattern with a reduced roughness can be formed at a lower dose even in a case where the pattern exposure with an electron beam and the subsequent UV batch exposure is performed in combination.

TABLE 2

| | Test 3-1 | Test 3-2 | Test 3-3 |
|---|---|---|---|
| | MOR | MOR/PP | MOR/PP |
| EB Dose (μC/cm²) | 1605 | 1595 | 1386 |
| UV (J/cm²) | 0 | 0 | 5 |
| LWR (nm) | 1.7 | 0.99 | 0.92 |
| LER (nm) | 2.1 | 1.8 | 1.6 |

Evaluation 4

Test 4-1: Photoresist Composition 1 (MOR)

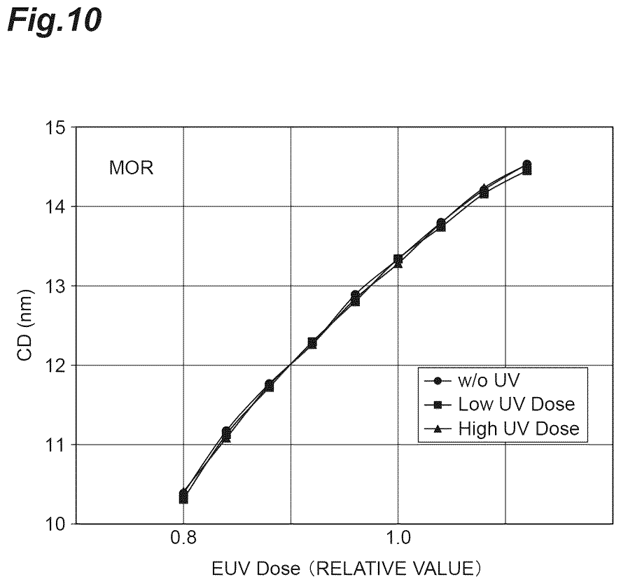

A spin-on glass film formed on a silicon wafer was coated with the photoresist composition 1 by using a spin coater. The coating film was heated at 100° C. for 60 seconds to remove the solvent, thereby forming a resist film having a thickness of 22 nm. In a vacuum, the entire surface of the resist film was irradiated with extreme ultraviolet rays (EUV) having a wavelength of 13.5 nm in a line/space pattern with a half pitch of 12 nm. Immediately thereafter, the entire surface of the resist film was exposed to ultraviolet rays having a wavelength of 365 nm at a low UV dose equivalent to an exposure amount of 3 J/cm² or a high UV dose equivalent to an exposure amount of 5 J/cm². Thereafter, the resist film was baked by heating at 160° C. for 60 seconds. The baked resist film was subjected to a development process using a developer solution containing propylene glycol monomethyl ether acetate (PGMEA) and acetic acid (AA). After the development process, the formed linear resist pattern was observed with a critical dimension SEM (CD-SEM) to measure the critical dimension (CD) of the resist pattern. The same test was performed under the conditions where the irradiation dose of EUV was different. Furthermore, the same test was performed under the condition where exposure to ultraviolet rays was not performed (w/o UV). FIG. 10 is a graph illustrating a relationship between the critical dimension (CD) and the irradiation dose (relative value) of EUV in Test 4-1.

### Test 4-2: Photoresist Composition 3 (MOR/PP)

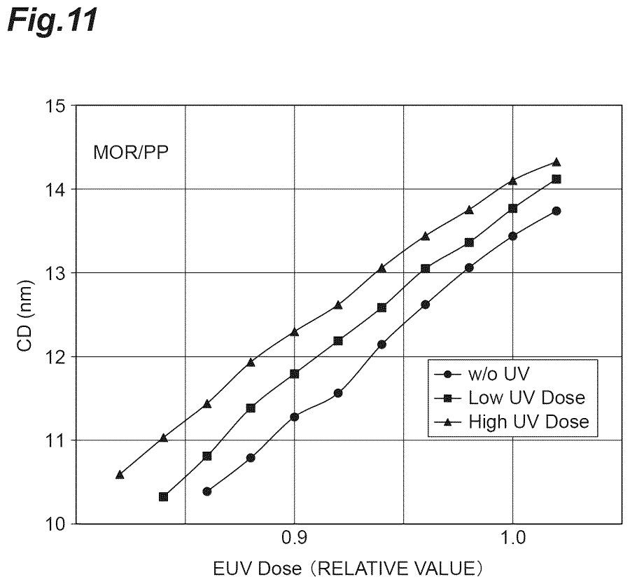

The photoresist composition 1 was mixed with a sensitizer precursor (PP) to obtain a liquid photoresist composition 3 containing 5% by mass PP. A test was performed in the same manner as in Test 4-2, except that the photoresist composition 3 was used instead of the photoresist composition 1. FIG. 11 is a graph illustrating a relationship between the critical dimension (CD) and the irradiation dose (relative value) of EUV in Test 4-2.

### Results

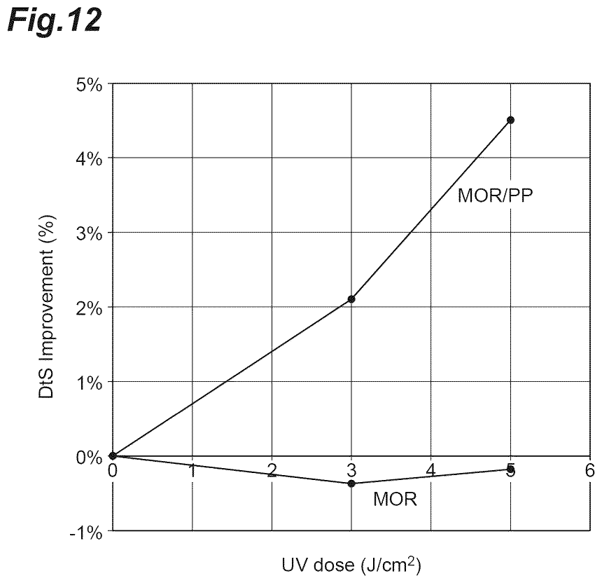

FIG. 12 is a graph illustrating the relationship between a CD-based increase rate (DtS improvement) of CD and the exposure amount of ultraviolet rays in a case where exposure to ultraviolet rays is not performed in Test 4-1 (MOR) or Test 4-2 (MOR/PP). It has been confirmed that the sensitivity is effectively improved by irradiation of the resist film containing the non-chemically amplified resist material (MOR) and the sensitizer precursor (PP) with ultraviolet rays.

### Evaluation 4

The solvent was removed from the film of the photoresist composition 3 containing the non-chemically amplified resist material (MOR) and the sensitizer precursor (PP) by heating at 110° C. for 60 seconds, thereby forming a resist film having a thickness of 22 nm. In a vacuum, the resist film was irradiated with extreme ultraviolet rays (EUV) having a wavelength of 13.5 nm in a pattern including circular portions having a diameter of 24 nm arranged at intervals of 48 nm. Thereafter, the resist film was baked by heating at 160° C. for 60 seconds. The baked resist film was developed with an aqueous tetramethylammonium hydroxide (TMAH) solution having a concentration of 2.38% by mass. By the development, the resist film in the circular portions irradiated with EUV was selectively removed. From this test, it has been confirmed that the photoresist composition containing the non-chemically amplified resist material (MOR) and the sensitizer precursor (PP) can also function as a positive resist material. As a result of performing the same test using the photoresist composition 1 devoid of a sensitizer precursor (PP), it has been confirmed that the resist film is developed as a negative resist material.

### REFERENCE SIGNS LIST

1: semiconductor wafer
3: etching target film
3A: patterned etching target film
3a, 5a: trench
5: resist film
5A: resist pattern
5E: part of resist film irradiated with first radiation
7: mask
R1: first radiation
R2: second radiation
11,12,13,14: processing module
20: substrate processing device
24: carrier block
25: processing block
26: interface block
30: exposure device
100: control device
C: carrier
W: workpiece
U1, U2: processing unit

1. A photoresist composition comprising:
a non-chemically amplified resist material; and
a sensitizer precursor,
wherein the sensitizer precursor is a compound that, upon irradiation with ionizing radiation or non-ionizing radiation having a wavelength of 300 nm or less, generates a sensitizer that absorbs non-ionizing radiation having a wavelength more than 300 nm.

2. The photoresist composition according to claim 1,
wherein the non-chemically amplified resist material is a metal oxide photoresist material.

3. The photoresist composition according to claim 1,
wherein the non-chemically amplified resist material is a main chain scission-type resist material.

4. The photoresist composition according to claim 1,
wherein the sensitizer precursor comprises at least one compound that generates the sensitizer having a carbonyl group and is selected from the group consisting of an acetal compound, a ketal compound, a thioacetal compound, an alcohol compound, a thiol compound,
and an orthoester compound.

5. The photoresist composition according to claim 1, further comprising:
a solvent.

6. A method for forming a resist pattern, comprising, in the following order:
irradiating a part of a resist film comprising a non-chemically amplified resist material and a sensitizer precursor with a first radiation;
irradiating an entire region including the part irradiated with the first radiation and other parts in the resist film with a second radiation in a batch; and
forming a resist pattern by removing a part of the resist film by development,
wherein the first radiation is ionizing radiation or non-ionizing radiation,
the second radiation is non-ionizing radiation,
in a case where the first radiation is non-ionizing radiation, the second radiation is non-ionizing radiation having a wavelength longer than a wavelength of the first radiation, and
the sensitizer precursor is a compound generating a sensitizer that absorbs the second radiation upon irradiation with the first radiation.

7. The method according to claim 6,
wherein the non-chemically amplified resist material is a metal oxide photoresist material.

8. The method according to claim 6,
wherein the non-chemically amplified resist material is a main chain scission-type resist material.

9. The method according to claim 6,
wherein the sensitizer precursor comprises at least one compound that generates the sensitizer having a carbonyl group and is selected from the group consisting of an acetal compound, a ketal compound, a thioacetal compound, an alcohol compound, a thiol compound,
and an orthoester compound.

10. The method according claim 6,
wherein the first radiation is ionizing radiation or non-ionizing radiation having a wavelength of 300 nm or less, and
the second radiation is non-ionizing radiation having a wavelength more than 300 nm.

11. The method according to claim 6, further comprising:
baking the resist film between the irradiation with the first radiation and the irradiation with the second radiation, after the irradiation with the second radiation, or between the irradiation with the first radiation and the irradiation with the second radiation and after the irradiation with the second radiation.

12. A method for manufacturing a semiconductor device having a patterned film, the method comprising:
forming a resist pattern on an etching target film by the method according to claim 6, the resist pattern having a trench in which the etching target film is exposed; and
etching the etching target film exposed in the trench such that the etching target film is patterned.

13. A substrate processing device comprising:
a film forming unit that forms a resist film comprising a non-chemically amplified resist material and a sensitizer precursor on a workpiece having an etching target film;
an exposure unit that irradiates the resist film having a part irradiated with a first radiation with a second radiation;
a development unit that forms a resist pattern by removing a part of the resist film by development; and
a control unit that controls the exposure unit such that an entire region including the part irradiated with the first radiation and other parts in the resist film is irradiated with the second radiation in a batch,
wherein the first radiation is ionizing radiation or non-ionizing radiation,
the second radiation is non-ionizing radiation, and
in a case where the first radiation is non-ionizing radiation, the second radiation is non-ionizing radiation having a wavelength longer than a wavelength of the first radiation.

14. The substrate processing device according to claim 13, further comprising:
a processing block that includes the film forming unit, the exposure unit, and the development unit; and
an interface block that includes a transport unit passing a workpiece having the resist film between the processing block and an exposure device irradiating a part of the resist film with the first radiation,
wherein the control unit controls the transport unit such that the workpiece having the resist film irradiated with the first radiation in the exposure device is transported to the exposure unit.

15. The substrate processing device according to claim 13,
wherein the film forming unit includes a coating unit that coats the workpiece with a photoresist composition comprising the non-chemically amplified resist material and the sensitizer precursor.

16. The substrate processing device according to claim 15,
wherein the film forming unit further includes a heat treatment unit that bakes a film of the photoresist composition to form the resist film comprising the non-chemically amplified resist material and the sensitizer precursor on the etching target film.
